(19) United States
(12) Patent Application Publication
(10) Pub. No.: US 2011/0157783 A1
(43) Pub. Date: Jun. 30, 2011

(54) BATTERY COVER MECHANISM

(75) Inventors: YI-FENG HUANG, Shindian (TW); KAI XU, Shenzhen City (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/791,061

(22) Filed: Jun. 1, 2010

(30) Foreign Application Priority Data
Dec. 24, 2009 (CN) 200910312203.3

(51) Int. Cl. H05K 5/00

(52) U.S. Cl. 361/679.01

(57) ABSTRACT

A battery cover mechanism used in a portable electronic device includes a housing and a cover, the housing has a fixing frame protruding therefrom and defines engaging recesses and latching grooves. The cover defines a cutout at an end and forms resisting bodies and hooks. When the cover is assembled to the housing, the resisting bodies resist against the housing to make the cover not touch the fixing frame, the resisting bodies correspondingly slides into the engaging recesses, the hooks latch into the latching grooves, and the fixing frame is received in the cutout.

### BACKGROUND

1. Technical Field

The present disclosure relates to battery cover mechanisms, particularly to a battery cover mechanism used in portable electronic devices.

2. Description of Related Art

A typical battery cover mechanism of portable electronic devices include a housing and a cover, the cover is slidably assembled with the housing to cover a battery. The housing generally forms a frame to receive a camera therein. However, the frame protrudes from the surface of the housing and accordingly can make the assembly of the cover inconvenient. Furthermore, the frame frictionally blocks the sliding of the cover relative to the housing, and the frame is prone to wear by the repeated sliding of the cover.

Therefore, there is room for improvement within the art.

### BRIEF DESCRIPTION OF THE DRAWINGS

Many aspects of the present battery cover mechanism can be better understood with reference to the following drawings. The components in the various drawings are not necessarily drawn to scale, the emphasis instead being placed upon clearly illustrating the principles of the present battery cover mechanism. Moreover, in the drawings, like reference numerals designate corresponding parts throughout the diagrams.

FIG. 1 is a disassembled view of the battery cover mechanism, according to an exemplary embodiment.

FIG. 2 is an assembled view of the battery cover mechanism shown in FIG. 1.

### DETAILED DESCRIPTION

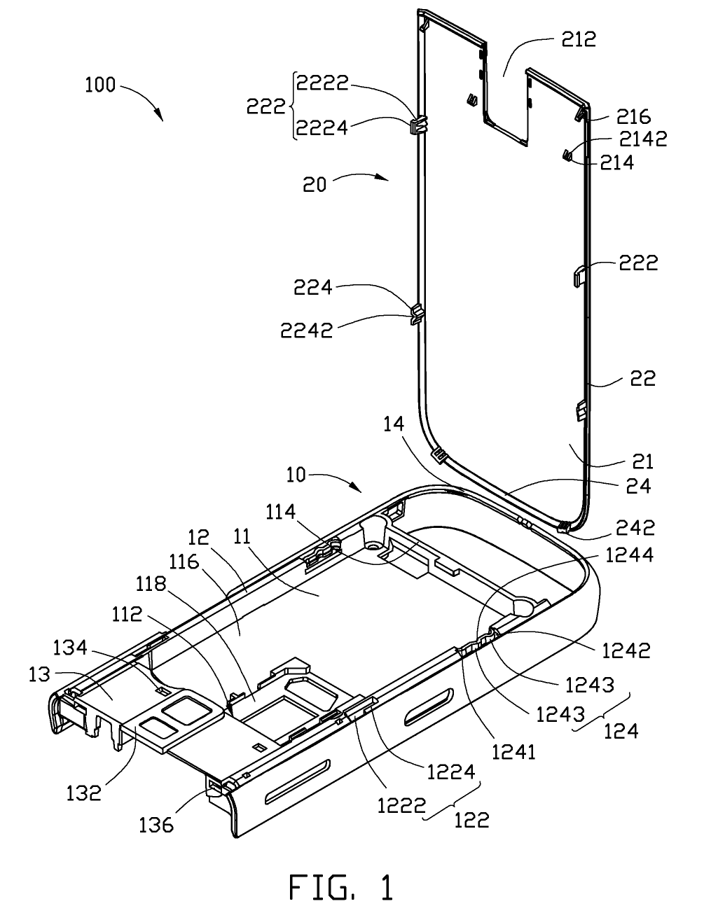

FIG. 1 shows the battery cover mechanism 100 used in mobile phones, and other portable electronic devices, such as personal digital assistants (PDAs), and digital cameras. The battery cover mechanism 100 includes a housing 10 and a cover 20 detachably assembled with the housing 10.

The hosing 10 includes a bottom plate 11, two substantially parallel sidewalls 12 substantially perpendicularly protruding from two sides of the bottom plate 11, a connecting plate 13 connecting the two sidewalls 12 at one of their ends, and an end wall 14 connecting the two sidewalls 12 at the other of their ends. The bottom plate 11 forms a substantially parallel first frame wall 112 and a second frame wall 114, each of which are substantially perpendicularly connecting the two sidewalls 12. The first frame wall 112 substantially perpendicularly connects to the connecting plate 13. Accordingly, the two sidewalls 12, the first frame wall 112 and the second frame wall 114 enclose a rectangular receiving chamber 116 to receive a battery. The bottom plate 11 defines an assembly cavity 118 located in a corner of the receiving chamber 116, the assembly cavity 118 is configured for receiving a chip card.

The two sidewalls 12 define two opposite latching grooves 122 and two opposite clamping grooves 124. Each latching groove 122 is substantially L-shaped and includes an inserting section 1222 and a latching section 1224. The inserting section 1222 has a larger width than the latching section 1224. The bottom of the latching section 1224 defines a space (not shown) with a substantially equal width as the inserting section 1222. The clamping groove 124 is substantially wave shaped and defines two clamping chambers 1243 spaced by a parting block 1244. The parting block 124 abuts a sidewall of the clamping groove 124 and forms a space with the sidewall, and the parting block 1244 is elastic and can be pressed.

The connecting plate 13 is substantially parallel to the bottom plate 11 and has a fixing frame 132 protruding from the top surface. The fixing frame 132 is used to secure electronic components such as cameras, or flashes. The connecting plate 13 defines two engaging recesses 134 at the two sides of the fixing frame 132 and adjacent to the first frame wall 112.

The cover 20 includes a plate portion 21, two side flanges 22 substantially perpendicular to two sides of the plate portion 21, and an end flange 24 connecting the two side flanges 22. The plate portion 21 defines a cutout 212 at an end opposite to the end flange 24, and the cutout 212 corresponds to fixing frame 132 in shape and size to receive the fixing frame 132. The plate portion 21 forms two resisting bodies 214 at two sides of the cutout 212, and the height of the resisting body 214 is slightly larger than the fixing frame 132. When the cover 20 is assembled, the resisting body 214 resists against the connecting plate 13 and correspondingly slides into the engaging recess 134. The resisting body 214 has a slanted surface 2142 to slide out of the engaging recess 134 smoothly. The two side flanges 22 forms two opposite hooks 222 and two opposite ribs 224. The hook 222 is used to latch into the latching groove 122. The hook 222 includes a supporting section 2222 and a hook section 2224, and the supporting section 2222 is substantially perpendicular to the plate portion 21. The hook section 2224 is formed at the distal end of the supporting section 2222 and bends toward the side flange 22. The rib 224 is used to engaging into the clamping groove 124. The rib 224 includes a protrusion 2242 laterally protruding relative to the side flange 22. The protrusion 2242 can be clamped in the clamping chamber 1243. The end flange 24 forms two stopping bodies 242 to resist against the end wall 14.

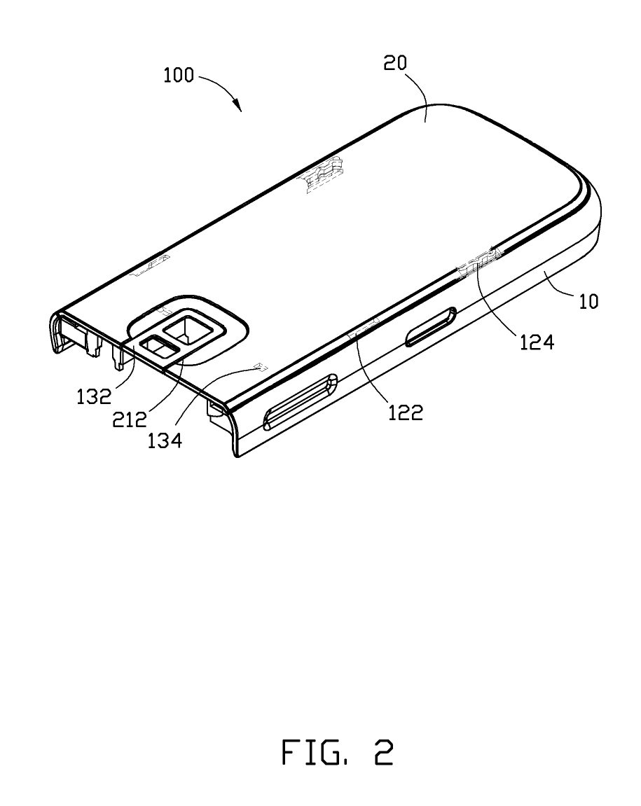

Referring to FIG. 2, to assemble the cover 20 to the housing 10, the hook 222 is placed into the inserting section 1222. The hook section 2224 resists against the bottom surface of the latching groove 122. The rib 224 is received in one of the clamping chambers 1243. The resisting body 214 resists against the connecting plate 13 to make the plate portion 21 separate from the fixing frame 132. Meanwhile, the end having the cutout 212 of the cover 20 is exposed from the connecting plate 13. Then, the cover 20 is pushed and moved towards the end wall 14. The hook portion 2224 of the hook 222 slides into the latching section 1224 and is limited in a perpendicular direction by the latching section 1224. The protrusion 2242 of the rib 224 presses the parting block 1244 and slides into the other clamping chamber 1243, and the rib 224 is clamped in the clamping chamber 1243. The resisting bodies 214 correspondingly slide into the two engaging recesses 134, and the cutout 212 receives the fixing frame 132 therein. The surface of the cover 20 and the top surface of the frame 132 are adjusted on substantially the same plane. The stopping bodies 242 resist against the inner side of the end wall 14.

To open the cover 20, the cover 20 is pulled and slides with the resisting bodies 214 withdraw from the engaging recesses 134. Meanwhile, the resisting bodies 214 raise the cover 20 so they do not touch the fixing frame 132. The hook portions 2224 slide into the inserting section 1222 from the latching section 1224, and the rib 224 slides into the original clamping chamber 1243. Then, the cover 20 is unlatched and can be easily removed.

It is noteworthy that, two fasteners 216 are formed at the end of the cover 20, and on the plate portion 21, adjacent to the cutout 212. The connecting plate 13 defines two receiving holes 136 correspondingly to engage with the fasteners 216.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A battery cover mechanism for a portable electronic device, comprising:
a housing having a fixing frame protruding therefrom, and the housing defining engaging recesses, latching grooves and clamping grooves;
a cover defining a cutout at an end of the cover and forming resisting bodies, hooks and ribs;
wherein when the cover is assembled to the housing, the resisting bodies resist against the housing to make the cover not touch the fixing frame, the resisting bodies correspondingly slides into the engaging recesses, the hooks latch into the latching grooves, the ribs are clamped in the clamping grooves, and the fixing frame is received in the cutout.

2. The battery cover mechanism as claimed in claim 1, wherein the housing includes a bottom plate, two sidewalls and two frame walls, the bottom plate, the two sidewalls and the two frame walls encloses a receiving chamber to receive battery.

3. The battery cover mechanism as claimed in claim 2, wherein the cover includes a plate portion and two side flanges formed at two side of the plate portion, each side flange forms a hook and a rib, each sidewall correspondingly forms a latching groove and a clamping groove.

4. The battery cover mechanism as claimed in claim 3, wherein the latching groove is “L”-shaped and includes an inserting section and a latching section, the inserting section is wider than the latching section, the hook latches into the latching section from the inserting section.

5. The battery cover mechanism as claimed in claim 3, wherein the clamping groove include two clamping chambers spaced by a parting block, the rib presses the parting block and slides into the other clamping chamber from one of the clamping chambers, and the rib is clamped in the clamping chamber.

6. The battery cover mechanism as claimed in claim 2, wherein the housing include a connecting plate connecting between the two sidewalls and parallel with the bottom plate, the fixing frame protrudes on the connecting plate, the connecting defines two engaging recesses at two sides of the fixing frame.

7. The battery cover mechanism as claimed in claim 2, wherein the housing includes an end wall connecting the two sidewalls, the cover has an end flange, the end flange forms two stopping bodies to resist against the inner side of the end wall after the cover is assembled with the housing.

8. The battery cover mechanism as claimed in claim 2, wherein the bottom plate defines an assembly cavity at a corner of the receiving chamber to receive a chip card.

9. The battery cover mechanism as claimed in claim 1, wherein the resisting body has a slanted surface for smoothly sliding out of the engaging recess.

10. The battery cover mechanism as claimed in claim 1, wherein the cover forms two fasteners adjacent to the end having the cutout, the housing defines two receiving holes to correspondingly engage with the fasteners.

11. A battery cover mechanism for a portable electronic device, comprising:
a housing having a fixing frame protruding therefrom, and the housing defining engaging recesses and latching grooves;
a cover defining a cutout at an end and forming resisting bodies, hooks;
wherein when the cover assembles to the housing, the resisting bodies resist against the housing to make the cover not touch the fixing frame, the resisting bodies correspondingly slides into the engaging recesses, the hooks latch into the latching grooves, and the fixing frame is received in the cutout.

12. The battery cover mechanism as claimed in claim 11, wherein the housing includes a bottom plate, two sidewalls and two frame walls, the bottom plate, the two sidewalls and the two frame walls encloses a receiving chamber to receive battery.

13. The battery cover mechanism as claimed in claim 12, wherein the cover includes a plate portion and two side flanges formed at two side of the plate portion, each side flange forms a hook, each sidewall correspondingly forms a latching groove.

14. The battery cover mechanism as claimed in claim 13, wherein the sidewall defines a clamping groove, the side flange forms a rib to correspondingly engaging into the clamping groove.

15. The battery cover mechanism as claimed in claim 11, wherein the cover forms two fasteners adjacent to the end having the cutout, the housing defines two receiving holes to correspondingly engage with the fasteners.

16. The battery cover mechanism as claimed in claim 12, wherein the housing include a connecting plate connecting between the two sidewalls and parallel with the bottom plate, the fixing frame protrudes on the connecting plate, the connecting defines two engaging recesses at two sides of the fixing frame.
